(19) United States
(12) Patent Application Publication
(10) Pub. No.: US 2026/0247573 A1
(43) Pub. Date: Aug. 20, 2026

(54) HEAT EXCHANGER FOR A SYSTEM FOR COOLING ELECTRONIC COMPONENTS

(71) Applicant: VALEO SYSTEMES THERMIQUES, La Verriere (FR)

(72) Inventors: Yvan LECHAT, La Verriere (FR); Luc DESTRO, La Verriere (FR); Michael LISSNER, La Verriere (FR); Morane CHAUMETTE-ORDONEZ, La Verriere (FR)

(73) Assignee: VALEO SYSTEMES THERMIQUES, La Verriere (FR)

(21) Appl. No.: 19/164,412

(22) PCT Filed: Mar. 11, 2024
(86) PCT No.: PCT/EP2024/056353

§ 371 Date: Oct. 22, 2025

(30) Foreign Application Priority Data
Mar. 14, 2023 (FR) FR2302366

(51) Int. Cl. H05K 7/20

(52) U.S. Cl. CPC H05K 7/20336; H05K 7/20318; H05K 7/20327

(57) ABSTRACT

A heat exchanger including a cooling plate configured to be in contact with electronic components and includes a circulation channel for a first heat-transfer fluid, and includes a two-fluid exchanger with a first fluid circuit in fluidic communication with the circulation channel of the cooling plate to form a circulation loop for the first heat-transfer fluid, and a second fluid circuit configured to receive a second heat-transfer fluid. The heat exchanger can also include an additional cooling plate arranged in contact with the two-fluid exchanger, and at least one heat-transfer element arranged between the additional cooling plate and a second part of the electronic components.

### TECHNICAL FIELD

The present invention relates to a heat exchanger for a system for cooling electronic components.

The servers used for data processing (commonly referred to as information technologies or “IT”) generally comprise printed circuit boards (PCBs) on which electronic components such as integrated circuits are arranged, which may include central processing units (CPUs), random access memory (RAM), etc. All of these electronic components generate heat during use. In order to keep the content of the servers at an optimal temperature so as to maximize the performance of the server, it is essential to discharge the heat generated thereby and/or to cool the components concerned.

### BACKGROUND OF THE INVENTION

In general, the electronic components that are used in servers are air-cooled. A heat sink with fins or similar elements for discharging heat into the surrounding air is generally used. Such a heat sink is then placed in contact with the surface of the electronic chip. This contact may be direct or otherwise be established via a thermal interface material between the two components. In addition to the heat sink, one or more fans may be used to circulate air so as to remove heat from the heat sink. Such a heat sink can be used in combination with cooling on the server installation side, such as air conditioning. However, this cooling method is not particularly effective. It also has a high operating cost and re-quires very large spaces to manage the air used for cooling.

Immersion liquid cooling is an alternative to air cooling. In some cases, liquid cooling allows more efficient heat transfer from the electronic components, resulting in greater cooling power. These liquids are, for example, dielectric fluids or mineral oil.

Liquids having a high specific heat capacity are particularly advantageous.

However, immersion liquid cooling imposes strong technical constraints related to the tightness of the casings in which the printed circuit boards are immersed, as well as the weight of these casings, which must be able to be supported by the buildings in which they are installed.

### SUMMARY OF THE INVENTION

It is therefore necessary to find a solution which makes it possible to dissipate heat efficiently from the electronic components of the servers while limiting the technical constraints imposed by this cooling of the electronic components.

To this end, the invention relates to a heat exchanger for a system for cooling electronic components, comprising:
a cooling plate configured to be in contact with a first part of the electronic components and comprising a circulation channel for a first heat-transfer fluid,
a two-fluid exchanger comprising a first fluid circuit in fluid communication with the circulation channel of the cooling plate so as to form a circulation loop for the first heat-transfer fluid and a second fluid circuit configured to receive a second heat-transfer fluid,
wherein the heat exchanger also comprises an additional cooling plate arranged in contact with the two-fluid exchanger and at least one heat transfer element arranged between the additional cooling plate and a second part of the electronic components.

Such an exchanger makes it possible to cool multiple separate elements or multiple separate circuits from a single source, thus simplifying the circuit. In addition, the cooling power can be adapted as a function of each of the components to be cooled.

According to another aspect of the present invention, the additional cooling plate is a passive cooling plate. Passive means that no fluid circulates in the cooling plate.

According to another aspect of the present invention, the heat transfer element is one of the following:
a metal spring such as a helical spring,
a flexible evaporator-condenser duct or heat pipe comprising a two-phase fluid that is configured to evaporate at a first end in contact with an electronic component and to condense at a second end in contact with the additional cooling plate.

According to another aspect of the present invention, the heat transfer element is screwed onto the additional cooling plate.

According to another aspect of the present invention, the additional cooling plate is screwed onto the two-fluid exchanger.

According to another aspect of the present invention, the additional cooling plate comprises a thermal foam arranged at the interface with the two-fluid exchanger, so as to maximize heat exchanges with the two-fluid exchanger. The thermal foam comprises, for example, a graphite sheet having a thickness of between 1 micron and a few millimeters.

According to another aspect of the present invention, the two-fluid exchanger comprises an aluminum support, preferably secured by brazing, on which the additional cooling plate is secured.

According to another aspect of the present invention, the two-fluid exchanger is a plate exchanger.

According to another aspect of the present invention, the first heat-transfer fluid circulating in the circulation loop is a two-phase fluid and the heat exchanger is configured to allow said two-phase fluid to evaporate as it passes through the circulation channel of the cooling plate and to condense as it passes through the first fluid circuit of the two-fluid exchanger.

According to another aspect of the present invention, the cooling plate is configured to control the flow rate of the two-phase fluid by capillary pumping.

According to another aspect of the present invention, the cooling plate comprises a porous structure forming a wick that is configured to control the flow rate of the two-phase fluid by capillary pumping.

According to another aspect of the present invention, the cooling plate comprises a floating valve that is configured to regulate the flow rate of the two-phase flu-id in liquid phase entering the circulation channel of the cooling plate as a function of the amount of two-phase fluid in liquid phase that is present in the circulation channel of the cooling plate, such that the greater the evaporation of the two-phase fluid in the cooling plate, the greater the flow rate of two-phase fluid in liquid phase entering the cooling plate.

The present invention also relates to a system comprising a heat exchanger as described above and electronic components, wherein the first part of the electronic devices is associated with a first thermal power and the second part of the electronic devices is associated with a second thermal power, which is less than the first thermal power.

According to another aspect of the present invention, the electronic devices are arranged on a printed circuit board, the first part of the electronic devices comprising one or more processors and the second part of the electronic devices comprising other components of the printed circuit board.

According to another aspect of the present invention, the system is a data server.

The present invention also relates to a method of using a heat exchanger as de-scribed above, comprising a circulation loop for a two-phase fluid connecting a hot source and a cold source and wherein the two-phase fluid is configured to evaporate as it passes through the hot source and to condense as it passes through the cold source.

According to another aspect of the present invention, the hot source comprises one or more electronic components and the cold source comprises a two-fluid exchanger.

### BRIEF DESCRIPTION OF THE DRAWINGS

Other advantages and features will become apparent upon reading the description of several illustrative but non-limiting examples of the present invention, as well as the appended drawings in which:

FIG. 1 is a schematic representation of a heat exchanger according to a first embodiment of the present invention;

FIG. 2 is a schematic representation of a heat exchanger according to a second embodiment of the present invention;

FIG. 3 is a schematic representation of a circulation loop for a two-phase fluid between two thermal devices;

FIG. 4 is a schematic representation of a cooling plate comprising a floating valve for regulating the flow rate of two-phase fluid.

### DETAILED DESCRIPTION OF THE INVENTION

In the figures, identical elements have the same reference signs.

The following embodiments are examples. Although the description refers to one or more embodiments, this does not necessarily mean that each reference sign refers to the same embodiment, or that the features apply only to one embodiment. Individual features of different embodiments can also be combined or interchanged to provide other embodiments.

In the present description, some elements or parameters may be indexed, such as for example first element or second element and also first parameter and second parameter or else first criterion and second criterion, etc. In this case, the indexing is used simply to differentiate between and designate elements or parameters or criteria that are similar but not identical. This indexing does not im-ply priority being given to one element, parameter or criterion over another and such designations can be easily interchanged without departing from the scope of the present description. Neither does this indexing imply any chronological order for example in assessing any given criterion.

The present invention relates to a heat exchanger for a system for cooling electronic components, in particular for electronic components of a data server.

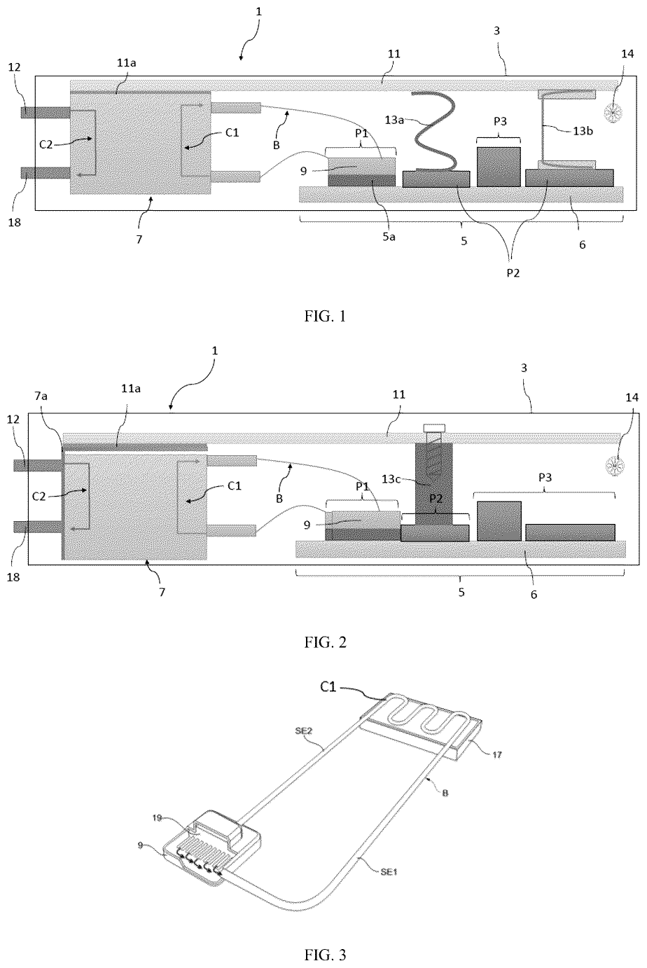

FIG. 1 represents a schematic view of such a heat exchanger 1 according to a first embodiment.

The electronic components 5 and the heat exchanger 1 can be arranged in a housing 3.

The various electronic components 5 can be associated with different thermal powers, that is to say they can generate more or less heat and therefore require a greater or lesser degree of heat dissipation to limit their temperature.

The electronic components 5 are, for example, subdivided into a first part P1 as-sociated with a first thermal power, a second part P2 associated with a second thermal power that is lower than the first thermal power, and a third part P3 as-sociated with a third thermal power that is lower than the second thermal pow-er.

The first part P1 of the electronic components 5 comprises, for example, a processor 5a (central processing unit (CPU)) or multiple processors 5a, the second part P2 of the electronic components 5 comprises, for example, random access memory (RAM) and/or a power supply and the third part comprises, for example, transistors and other simple electronic components.

All of the electronic components 5 can be arranged on a single printed circuit board (PCB) 6.

The heat exchanger 1 comprises a cooling plate 9 configured to be in contact with the first part P1 of the electronic components 5, here the processor 5a. The cooling plate 9 comprises a circulation channel configured to receive a first heat-transfer fluid.

The heat exchanger 1 also comprises a two-fluid exchanger 7.

The two-fluid exchanger 7 comprises a first fluid circuit C1 in fluid communication with the circulation channel of the cooling plate 9 so as to form a circulation loop B for the first heat-transfer fluid.

The first heat-transfer fluid is, for example, a two-phase fluid configured to evaporate as it passes through the cooling circulation channel 9 and to condense as it passes through the first fluid circuit C1 of the two-fluid exchanger.

The two-fluid exchanger 7 also comprises a second fluid circuit C2 configured to receive a second heat-transfer fluid.

The inlet of the second fluid circuit C2 is, for example, connected to a duct 12 for supplying the second heat-transfer fluid. The supply duct 12 may be a duct which feeds various cabinets (racks) of the data server and may be connected to a central heat exchanger (not shown) of the data server.

The outlet of the second fluid circuit C2 is, for example, connected to a return duct 18 for the second heat-transfer fluid. The return duct 18 for the heat-transfer fluid is, for example, connected to the central heat exchanger of the data server. The second heat-transfer fluid is for example water or glycol water.

The two-phase fluid in the circulation loop B is selected so that, during its circulation in the circulation loop B, the two-phase fluid evaporates as it passes through the cooling plate 9 which, together with the first part P1 of the electronic components 5, constitutes a hot source and to condense as it passes through the two-fluid exchanger 17, which constitutes a cold source. This evaporation and this condensation make it possible to circulate the two-phase fluid in the circulation loop B, the flow rate of the two-phase fluid being greater the higher the temperature of the cooling plate 9.

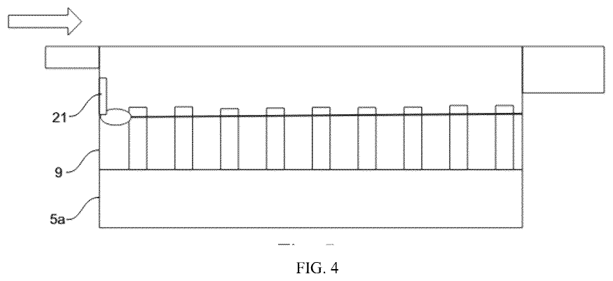

According to a variant embodiment shown in FIG. 3, the circulation loop B comprises a porous structure 19 forming a wick at the cooling plate 9. The porous structure 19 is arranged in the two-phase-fluid circulation channel of the cooling plate 9. The porous structure 19 is configured to control the flow rate of the two-phase fluid by capillary pumping. Indeed, the gaseous phase of the two-phase fluid evaporated in the cooling plate 9 returns to the two-fluid exchanger 17 via a first section SE1 of the circulation loop B. This evaporation leads to the intake of the two-phase fluid in liquid phase coming from the two-fluid ex-changer 17 into the second section SE2 of the circulation loop B, the two-phase fluid condensing as it passes through the two-fluid exchanger 17.

According to an alternative variant embodiment shown in FIG. 4, the circulation loop B comprises a floating valve 21 at the cooling plate 9. The floating valve 21 is arranged in the two-phase-fluid circulation channel of the cooling plate 9. The floating valve 21 is configured to regulate the flow rate of the two-phase fluid in liquid phase entering the cooling plate 9 as a function of the amount of two-phase fluid in liquid phase that is present in the cooling plate 9 such that the greater the evaporation of the two-phase fluid in the cooling plate 9, the lower the level of the floating valve 21 and the greater the flow rate of two-phase fluid in liquid phase coming from the two-fluid exchanger 17 and entering the cooling plate 9. The two-phase fluid in gaseous phase evaporated in the cooling plate 9 returns to the two-fluid exchanger 17 via the circulation loop B. The two-phase fluid is then condensed in the two-fluid exchanger 17 to return to the cooling plate 9 in the liquid state.

Thus, the two-phase fluid can circulate in the circulation loop B without requiring a pump and without any input of energy other than the heat produced by the processor 5a in contact with the cooling plate 9.

The heat exchanger 1 also comprises an additional cooling plate 11 arranged in contact with the two-fluid exchanger 7 and in particular in the vicinity of the second fluid circuit C2 in which the second heat-transfer fluid circulates.

The additional cooling plate 11 may be passive, that is to say not have a fluid circulation channel. The additional cooling plate 11 in particular allows heat ex-change by conduction. The additional cooling plate 11 may be a metal plate, in particular made of steel or aluminum.

The additional cooling plate 11 may comprise a thermal foam (thermal pad) arranged at the interface with the two-fluid exchanger 7 to maximize heat ex-change with the two-fluid exchanger 7. The thermal foam comprises, for example, a graphite sheet with a thickness of between 100 microns and a few milli-meters. The thermal foam may also include other elements such as silicone.

The heat exchanger 1 also comprises at least one heat transfer element arranged between the additional cooling plate 11 and the second part P2 of the electronic components 5. The heat transfer element is in contact, on the one hand, with the additional cooling plate 11 at a first end and, on the other hand, with at least one of the electronic components 5 of the second part P2 of the electronic com-ponents 5.

The heat transfer element is, for example, a metal spring 13a such as a helical spring.

The heat transfer element can also be a flexible evaporator-condenser duct 13b, also known as a heat pipe, containing a two-phase fluid configured to evaporate at a first end of the heat transfer element in contact with the electronic component(s) 5 of the second part P2 and to condense at the second end of the heat transfer element in contact with the additional cooling plate 11.

The heat transfer element may also be made of a thermally conductive material such as a plastics material filled with metal particles or any other material having a high thermal conductivity (for example >1 W. m−1·K−1). The heat transfer element is, for example, screwed onto the additional cooling plate 11 like the heat transfer element 13c of FIG. 2. The heat transfer element may also be glued.

A fan 14 may also be arranged in the housing 3 to promote cooling of the electronic components by convection, in particular for the electronic components 5 of the third part P3 which are not in contact with a heat transfer element. The heat produced by the electronic components of the third part P3 is then transferred to the two-fluid exchanger 7 by convection via the air present in the housing 3. In the absence of a housing 3, the heat of the components of the third part is dissipated into the surrounding air.

The present invention also relates to a system comprising a heat exchanger 1 as described above and electronic components 5. The system is, for example, a da-ta server comprising a plurality of heat exchangers 1 as described above connected to a central heat exchanger and a general circuit allowing the circulation of the heat-transfer fluid to the various heat exchangers via a supply duct 12 and a return duct 18.

The present invention also relates to a method of using a heat exchanger 1 as de-scribed above, comprising a circulation loop for a two-phase fluid, for example the circulation loop B, connecting a hot source, for example the cooling plate 9 in contact with the processor 5a, and a cold source, for example the two-fluid exchanger 7, and in which the two-phase fluid is configured to evaporate as it passes through the hot source, here the cooling plate 9, and to condense as it passes through the cold source, here the two-fluid exchanger 7. The flow rate of the two-phase fluid is, for example, controlled by a floating valve 21 or a porous structure 19 forming a wick that is configured to perform capillary pumping.

Thus, the present invention makes it possible, by using a heat exchanger 1 comprising at least two separate cooling devices for different electronic components 5 having different thermal powers on the basis of a single heat-transfer fluid, to cool the different electronic components 5 in a simple and efficient manner while limiting the weight of the cooling device for the electronic components 5.

What is claimed is:

1. A heat exchanger for a system for cooling electronic components, comprising:
a cooling plate configured to be in contact with a first part of the electronic components and including a circulation channel for a first heat-transfer fluid,
a two-fluid exchanger comprising-including a first fluid circuit in fluid communication with the circulation channel of the cooling plate so as to form a circulation loop for the first heat-transfer fluid and a second fluid circuit configured to receive a second heat-transfer fluid,
an additional cooling plate arranged in contact with the two-fluid exchanger and at least one heat transfer element arranged between the additional cooling plate and a second part of the electronic components,
wherein the additional cooling plate is a passive cooling plate.

2. The heat exchanger as claimed in claim 1, wherein the heat transfer element is one of the following:
a metal spring,
a flexible evaporator-condenser duct with a two-phase fluid that is configured to evaporate at a first end in contact with an electronic component and to condense at a second end in contact with the additional cooling plate.

3. The heat exchanger as claimed in claim 2, wherein the heat transfer element is screwed onto the additional cooling plate.

4. The heat exchanger as claimed in claim 1, wherein the two-fluid exchanger includes an aluminum support secured by brazing, on which the additional cooling plate is secured.

5. The heat exchanger as claimed in claim 1, wherein the two-fluid exchanger is a plate exchanger.

6. The heat exchanger as claimed in claim 1, wherein the first heat-transfer fluid circulating in the circulation loop is a two-phase fluid, the heat exchanger being configured to allow the two-phase fluid to evaporate as it passes through the circulation channel of the cooling plate and to condense as it passes through the first fluid circuit of the two-fluid exchanger.

7. The heat exchanger as claimed in claim 6, wherein the cooling plate is configured to control the flow rate of the two-phase fluid by capillary pumping.

8. The heat exchanger as claimed in claim 7, wherein the cooling plate comprises-includes a floating valve that is configured to regulate the flow rate of the two-phase fluid in liquid phase entering the circulation channel of the cooling plate as a function of the amount of two-phase fluid in liquid phase that is present in the circulation channel of the cooling plate, such that the greater the evaporation of the two-phase fluid in the cooling plate, the greater the flow rate of two-phase fluid in liquid phase entering the cooling plate.

9. (canceled)
